(19) United States
(12) Patent Application Publication
(10) Pub. No.: US 2003/0010378 A1
(43) Pub. Date: Jan. 16, 2003

(54) Solar cell module

(76) Inventors: Hiroyuki Yoda, Kitakatsuragi-gun (JP); Akimasa Umemoto, Sakurai-shi (JP)

Correspondence Address: NIXON & VANDERHYE P.C., 8th Floor, 1100 North Glebe Road, Arlington, VA, 22201, US

(21) Appl. No.: 10/191,805

(22) Filed: Jul. 10, 2002

(30) Foreign Application Priority Data
Jul. 13, 2001 (JP) 2001-213915 (P)

(51) Int. Cl. H01L 31/00

(52) U.S. Cl. 136/251; 136/244

(57) ABSTRACT

Two sheet glasses are superposed at a prescribed distance with a spacer interposed. By these two sheet glasses and a spacer, a double glazing glass having a sealed inner space is formed. In the inner space of the double glazing glass, a plurality of solar cells that have been subjected to weather resistant sealing process are provided. As a result, a double glazing glass type solar cell module is obtained, which is lightweight, of which manufacturing process is simple and which has high reliability over a long period of time.

### BACKGROUND OF THE INVENTION

1. Field of the Invention

The present invention relates to a solar cell module provided with solar cells.

2. Description of the Background Art

Conventionally, double glazing glass (a pair glass) has been known which has such a structure in that two sheet glasses are superposed at a prescribed distance with a metal spacer (for example, made of aluminum) placed therebetween. Such double glazing glass has a sealed air layer (internal space) sandwiched between the two sheet glasses. Thus, the double glazing glass has superior sound insulation and thermal insulation effects. Therefore, the double glazing glass is used for windows on the outer wall, ceiling or outdoor top light at places where thermal insulation is necessary and at houses, buildings and passages where lightening and sound insulation are necessary.

Recently, the problem of energy has been attracting attention. As a solution to the energy problem, attachment of a solar cell module to the double glazing glass having the above described structure has been studied.

A solar cell module of the double glazing glass type (a solar cell module having the shape of double glazing glass in appearance) includes, as shown in FIG. 5, a sheet glass (back cover glass 121) such as a tempered glass, a net-embedded glass 122, a spacer 123 and air-tight and waterproof sealing members 131 and 132, similar to a conventional general double glazing glass.

There is a sealed space (inner space 102A) inside the double glazing glass. Further, on an outer surface of double glazing glass 102, a solar cell module 101 having a laminated glass structure is superposed.

In the aforementioned solar cell module 101 having the laminated glass (double glasses) structure, a solar cell 110 is provided between a front cover glass and a back cover glass 102. The front cover glass and a back cover glass both has high strength and weather resistance. Between each of the two cover glasses and the solar cell 110, a filler having buffering property and weather resistance is laminated.

When the solar cell module 101 having such a laminated glass structure is mounted on double glazing glass 102, it follows that a total of four sheet glasses are used for solar cell module 101. Thus, solar cell module 101 becomes heavy. In order to solve this problem, the back cover glass of the solar cell module having the laminated glass structure may also be used as the upper sheet glass of the glazing glass, so that the number of sheet glasses can be reduced by one.

Even when the number of sheet glasses is reduced by one, the conventional solar cell module shown in FIG. 6 still requires use of three sheet glasses, that is, front cover glass 111, back cover glass 121 and net-embedded glass 122, which are large and thick. Thus, the solar cell module is still considerably heavy. As a result, when the solar cell module described above is to be mounted on a building, a special sash frame or the like must be used. Further, the building itself must have a structure with sufficient strength that can withstand attachment of the heavy body. Therefore, use of the solar cell module of the conventional glazing glass type increases the cost of construction work of the building.

The solar cell module of the glazing glass type shown in FIG. 6 is manufactured through the following steps.

First, on front cover glass 111, filler 112, a plurality of solar cells 110 connected to each other, filler 112 and back cover glass 121 (upper sheet glass of glazing glass 102) are stacked successively in this order. Thereafter, using a large apparatus such as a laminator (vacuum heating and pressing apparatus), pressure is applied to back cover glass 121, so as to cure the filler 112. As a result, a solar cell module of the laminated glass structure is completed.

Thereafter, on back cover glass 121, spacer 123 is adhered by using a large apparatus, with an air-tight and water proof sealing member 131 interposed. Thereafter, on spacer 123, net-embedded sheet glass 122 is superposed. Thus the double glazing glass is formed. Thereafter, along the peripheral portion of double glazing glass 102, air-tight and waterproof sealing member 132 is applied or adhered. Thus, a window with the solar cell module is finished.

The manufacturing method described above, however, requires use of a large apparatus for a long period of time. This result in higher manufacturing cost.

Further, in order to form a solar cell module of laminated glass structure having a large area, it is necessary to cure the filler by once applying pressure to the back cover glass 121 of large area, using a large apparatus such as the laminator.

It is difficult, however, to delicately control the pressure applied to solar cell 110 during the curing process, as heating becomes uneven because of variation in thickness of filler 112, for example. This may possibly result in crack in the solar cell.

When solar cell is cracked after the end of curing filler 112, solar cell 110 must be exchanged. Even when only one solar cell 110 is cracked, the front cover glass 111 or back cover glass 121 must be broken, in order to exchange the solar cell. Therefore, when solar cell 110 is cracked after the end of the curing process step, the solar cell module of laminated glass structure having a large area must be discarded as a defective unit. As a result, production yields of the solar cell modules lower, significantly increasing the cost for the solar cell modules.

In order to solve the above described problem, it may be possible to reduce the weight of the three sheet glasses, that is, front cover glass 111, back cover glass 121 and net-embedded glass 122 that are heavy, large sized thick plates, by replacing the glasses with glasses of other material.

In order to ensure weather resistance and rigidity in compliance with the standard of the solar cell module, however, it is necessary to use one of the various sheet glasses such as blue sheet glass, white sheet glass, figured glass, tempered glass or double-tempered glass, as the front cover glass. Further, when the solar cell module of the double glazing glass type is to be used at a lighting portion of an arcade or as a top light of a building as a living space, it is necessary to use a net-embedded glass, that is, one of the aforementioned various types of glasses with net-embedded therein, in view of safety.

Therefore, in order to reduce weight and simplify the method of manufacturing the solar cell module of double glazing glass type having such a structure as shown in FIG. 6, an only method available is to eliminate back cover glass 121, from the three sheet glasses, that is, front cover glass 111, back cover glass 121 and net-embedded glass 122.

The back cover glass 121 may be eliminated by the following method. First, a double glazing glass similar to the conventional one is formed by using a front cover glass, a net-embedded glass, a spacer and air-tight and waterproof sealing members. In the inner space of the double glazing glass, solar cell is directly attached. The solar cell module of such a structure is disclosed in Japanese Utility Model Laying-Open No. 61-177464 and Japanese Patent Laying-Open Nos. 10-1334 and 11-31834.

In the solar cell modules disclosed in these references, however, the surface of the solar cell directly attached in the inner space of the double glazing glass is in direct contact with air or inert gas sealed in the inner space of the double glazing glass. Thus, air-tightness and waterproof property of the solar cell cannot be ensured by the sealing members only.

Further, the solar cell is fixed on the front cover glass or on the net-embedded glass by means of an adhesive tape or the like. Here, it is noted that a metal portion of the solar cell electrode is in contact with glass. Thus, there is heat transmission between the metal portion of the solar cell electrode and the glass. As a result, when the solar cell module is exposed to strong sunlight, there is a possibility that the glass is cracked because of heat. Further, there is a possibility that the solar cell is cracked, because of a large difference in coefficient of linear expansion between the solar cell and the glass. The solar cell module as such lacks reliability over long period of use.

### SUMMARY OF THE INVENTION

An object of the present invention is to provide a solar cell module which is lightweight, of which manufacturing process is simple and which ensures reliability over a long period of time.

The solar cell module according to the present invention has a double glazing glass in which two sheet glasses are superposed at a prescribed distance with a spacer interposed, and a sealed inner space is formed by the two sheet glasses and a spacer. In the inner space of the double glazing glass, a plurality of solar cells that have been subjected to weather resistant sealing process are attached.

In the solar cell module of the present invention, the weather resistant sealing process performed on the plurality of solar cells may be a process in which each of the plurality of solar cells is covered with a transparent filler and a weather resistant and transparent film. In the solar cell module of the present invention, the weather resistant sealing process performed on the plurality of solar cells may be a process in which all the plurality of solar cells after the end of connecting process are integrally covered by the transparent filler and a weather resistant and transparent film.

In the solar cell module of the present invention, preferably, a transparent resin of ethylene vinyl acetate or polyvinyl butyral is used as the transparent filler used for the weather resistant sealing process. In the solar cell module of the present invention, polyethylene terephthalate or fluorine based resin film is used as the weather resistant and transparent film.

In the solar cell module of the present invention, a plurality of solar cells may be attached on the surface facing the inner space of the sheet glass on the sunlight receiving side (font cover glass) or on the surface facing the inner space of the sheet glass of sunlight non-receiving side (back cover glass), of the double glazing glass, by using a fixing member for attachment. As the fixing member for attachment, a transparent adhesive tape or a transparent resin such as ethylene vinyl acetate or polyvinyl butyral is preferably used.

In the solar cell module of the present invention, any of blue sheet glass, white sheet glass, figured glass, tempered glass and double-tempered glass is preferably used, for the two sheet glasses forming the double glazing glass. Further, as the sheet glass on the sunlight non-receiving side (back cover glass), a net-embedded glass, that is, any of the blue sheet glass, white glass, figured glass, tempered glass and double-tempered glass with a net-embedded therein, is preferably used.

The solar cell module of the present invention specifically has the following structure.

The spacer used for the double glazing glass is formed of metal or hard resin. On a side surface of the spacer, a terminal or a lead is provided for taking output power of the plurality of solar cells to the outside. The terminal or the lead portion is sealed by an air-tight and waterproof hermetic seal. Further, at a peripheral portion of the aforementioned double glazing glass, in order to seal a gap between the double glazing glass and a spacer, an air-tight and waterproof seal is established by using at least one sealing member of silicone, polysulfide and rubber.

In the solar cell module of the present invention, the solar cell is moleded by a transparent resin based filler such as ethylene vinyl acetate or polyvinyl butyral.

Further, the solar cell is covered with a weather resistant and transparent resin film of polyethylene terephthalate or a fluorine based resin. Namely, the solar cell is subjected to weather resistant sealing process.

The plurality of solar cells that have been subjected to the weather resistant sealing process are attached, in the similar manner as the conventional solar cell module, in the inner space of the double glazing glass. Therefore, only two sheet glasses are used for the sheet glasses of a double glazing glass type solar cell module of the present invention. Thus, the solar cell module is lightweight.

In the weather resistant sealing process of the solar cell, it is possible to use only a small sized laminator, without using a manufacturing apparatus such as a large laminator. Thus, the solar cell module of the present invention provides the following function and effects.

The conventional solar cell module of the laminated glass structure is manufactured by curing the filler, by applying pressure, using a manufacturing apparatus such as a large laminator, to the front cover glass, solar cell trains, the filler and the back cover glass.

By contrast, the solar cell module of the present invention is manufactured through the following manufacturing steps. First, a single or a plurality of solar cells are sandwiched by a transparent resin based filler and a weather resistant and transparent resin film, by using a small sized laminator or the like. Namely, the solar cell is subjected to weather-resistant processing. The plurality of solar cells that have been subjected to weather-resistant sealing are connected to each other to form a module. Using a transparent adhesive tape or a transparent resin such as ethylene vinyl acetate or polyvinyl butyral, the solar cell is adhered on the sheet glass (the sheet glass on the sunlight receiving side or sunlight non-receiving side) forming the double glazing glass. Thus, by using a double glazing glass manufacturing apparatus similar to the conventional one, the double glazing glass type solar cell module is completed.

Therefore, according to the method of manufacturing the solar cell module of the present invention, it becomes possible to exchange a cracked solar cell with a new solar cell, that has been impossible in accordance with the conventional method of manufacturing a solar cell module having the laminated glass structure. Thus, the steps for manufacturing the module can be simplified and production yield of the module can be improved. Thus, manufacturing cost of the solar cell module is reduced.

Further, as the solar cell that has been subjected to weather resistant sealing process is attached to the sheet glass in the inner space of the double glazing glass, the sealing member which has been subjected to the weather resistant sealing process functions as a buffer, as it has a prescribed thickness. Thus, the solar cell is not in direct contact with the sheet glass forming the double glazing glass. As a result, the metal portion of the solar cell electrode is not in contact with the sheet glass forming the double glazing glass.

Therefore, the possibility of thermal crack of the glass or crack of the solar cell cased by the difference in coefficient of linear expansion between the solar cell and the sheet glass forming the double glazing glass when the solar cell module is exposed to strong sunlight can be reduced. Thus, reliability of the solar cell module over a long period of time can be ensured.

It is possible that moisture enters the inner space of the double glazing glass from the outside, when the sealing member (air-tight and waterproof sealing member) as a part of the double glazing glass deteriorates. Even in that case, the reliability over long period of time generally required of a solar cell module is not impaired, as the solar cell itself is subjected to the weather resistant sealing process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross section of the solar cell module in accordance with a first embodiment.

FIG. 2 is an exploded perspective view of the solar cell module in accordance with the first embodiment.

FIG. 3 is a partial cross section of the solar cell module in accordance with a second embodiment.

FIG. 4 is a perspective view of a main portion schematically showing a sealed structure of the external terminal portion for outputting power from the solar cell arranged in the inner space of the double glazing glass.

FIG. 5 is a partial cross section of the conventional double glazing glass type solar cell module.

FIG. 6 is an exploded perspective view of the conventional double glazing glass type solar cell module.

### DESCRIPTION OF THE PREFERRED EMBODIMENTS

The solar cell module in accordance with the embodiment of the present invention will be described with reference to the figures.

First Embodiment

The solar cell module in accordance with the present embodiment is a double glazing glass type solar cell module having an inner space sandwiched by two sheet glasses with a spacer interposed.

In the solar cell module of the present embodiment, a plurality of solar cells that have been subjected to weather resistant sealing process by a transparent resin based filler and weather resistant and transparent resin film are provided in the inner space of the double glazing glass. In the method of manufacturing a solar cell module of the present embodiment, a plurality of solar cells are fixed on the double glazing glass by means of a transparent adhesive tape or the like and, thereafter, air-tight and waterproof seal is provided around the spacer. The solar cell module of the present embodiment and the double glazing glass type solar cell module of the same shape as the solar cell module disclosed in Japanese Patent Laying-Open No. 11-31834, for example, have, in appearance, the same structure.

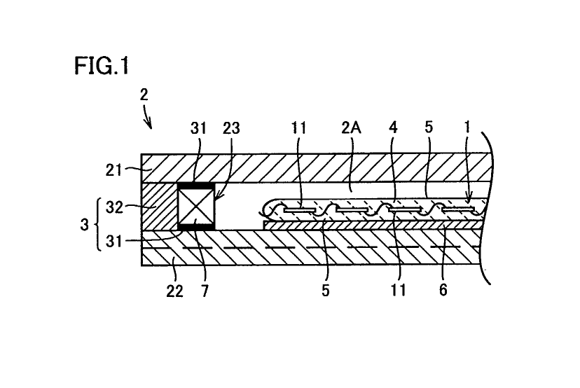

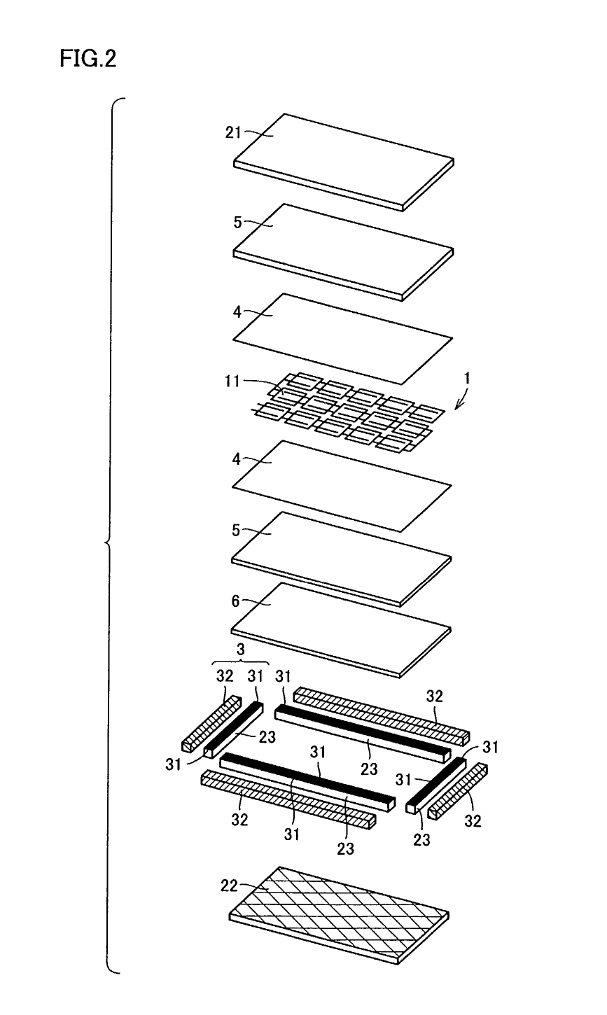

The solar cell module of the present embodiment will be described in the following with reference to FIGS. 1 and 2.

The solar cell module of the present embodiment includes, as shown in FIGS. 1 and 2, a front cover glass 21, a net-embedded glass 22, a spacer formed of metal such as aluminum or a hard resin, and a solar cell train 1. Solar cell train 1 includes a plurality of solar cells 1 connected to each other to form a module. The solar cell train 1 has been subjected to weather resistant sealing process.

A solar cell module of the present embodiment has a double glazing glass structure 2 in which spacer 23 is sandwiched between front cover glass 21 and net-embedded glass 22. The solar cell train 1 is provided in the inner space 2A formed by the double glazing glass structure 2.

In inner space 2A, between each of front cover glass 21 and net-embedded glass 22 and spacer 23, an air-tight and waterproof seal member 3 (primary seal member 31, secondary seal member 32) is inserted. Further, by the air-tight and waterproof sealing member 3 (primary sealing member 31 and secondary sealing member 32), air tightness of inner space 2A is maintained.

Of the two sheet glasses forming the double glazing glass, as the front cover glass 21 positioned on the sunlight receiving side, a sheet glass of any of blue sheet glass, white sheet glass, figured glass, tempered glass and double-tempered glass is used. Of the two sheet glasses forming the double glazing glass 2, as the net-embedded glass 22 positioned on the sunlight non-receiving side, a net-embedded glass prepared by embedding net in a sheet glass of any of blue sheet glass, white sheet glass, figured glass, tempered glass and double-tempered glass is used. As the sheet glass placed on the sunlight non-receiving side, the same sheet glass as front cover glass 21 may be used. It is noted, however, that when the solar cell module is installed at a lighting portion of an arcade or provided as a top light of a building, it is possible that when the sheet glass should be broken because of the heat from the sun, injury of a person therebelow is possible. Therefore, a net-embedded glass is desirably used as the sheet glass on the sunlight non-receiving side.

The solar cell train 1 is subjected to weather resistant processing, using a transparent filler 4 such as ethylene vinyl acetate or polyvinyl butyral, and a weather resistant and transparent film 5 such as polyethylene terephthalate or fluorine based resin film.

The solar cell train 1 is adhered on the inner surface (the surface facing inner space 2A) of net-embedded glass 22 by using a transparent adhesive tape 6 such as ethylene vinyl acetate or polyvinyl butyral. As an adhesive member for solar cell train 1, a transparent resin such as ethylene vinyl acetate or polyvinyl butyral may be used.

In the solar cell module of the first embodiment shown in FIGS. 1 and 2, a plurality of solar cells 11 that have been already connected to each other are subjected to a laminating step, in which the weather resistant sealing process is performed by using transparent filler 4 and weather resistant and transparent film 5. In the laminating step, a large laminator (vacuum heating and pressurizing apparatus) is used.

According to the method of manufacturing the solar cell module of the present embodiment, the members integrated by applying a large pressure using the vacuum heating and pressurizing apparatus include the solar cell 11, transparent filler 4 and weather resistant and transparent film 5, only. Therefore, when a cracked solar cell is identified after the step of laminating, the cracked solar cell can be replaced by a good solar cell 11 without breaking the front cover glass 21 or back cover glass 22. More specifically, the cracked solar cell can be cut out and a new solar cell can be placed into the portion where the cracked solar cell has been removed, without breaking front cover glass 21 or back cover glass 22.

Thereafter, the solar cell train 1 having the cracked solar cell replaced by the good solar cell 11 is again subjected to laminating process. Thus, unlike the conventional solar cell module having laminated glass structure, the problem that the entire module must be discarded because of a cracked solar cell can be avoided. As a result, production yield of the solar cell modules of the present embodiment is improved, and hence the cost of the product can be reduced.

After the above described step of laminating, spacer 23 is adhered to the peripheral portion of net-embedded glass 22 with air-tight and waterproof sealing member 3 (primary sealing member 31) interposed, using a large apparatus for manufacturing the double glazing glass 2. Thereafter, on spacer 23, front cover glass 21 is superposed, with the air-tight and waterproof sealing member 3 (primary sealing member 31) interposed. Thus the double glazing glass is formed. Around the peripheral portion of the double glazing glass, air-tight and waterproof sealing member 3 (secondary sealing member 32) is applied or adhered. Thus, the double glazing glass type solar cell module is completed.

At this time, inner space 2A is set to a dry air state by using a desiccant 7 such as silica gel placed in spacer 23, to an inert gas filled state, or to a vacuum state. As the material of air-tight and waterproof sealing member 3 (primary sealing member 31 and secondary sealing member 32), silicone, polysulfide or rubber is suitably used.

In the solar cell module of the present embodiment described with reference to FIGS. 1 and 2, a plurality of solar cells 11 that have already been connected to each other are integrally subjected to weather resistant sealing process, using the transparent filler 4 and weather resistant and transparent film. The weather resistant sealing process of the solar cell is not limited to the one described above. Using a small size laminator, each solar cell 11 or a plurality of solar cells 11 forming a train 1 of solar cells may be subjected separately to the weather resistant sealing process.

In that case, when the solar cells are adhered on the inner surface of net-embedded glass 22 by transparent adhesive tape 6 (or transparent resin), the solar cells 11 (that have been subjected to weather resistant sealing process) of the number necessary for forming a module can be connected to each other.

When the solar cell train 1 is formed by such a method, exchange of a cracked solar cell 11 by a new solar cell 11 is further facilitated, when a few solar cells 11 among the plurality of solar cells 11 is cracked.

Second Embodiment

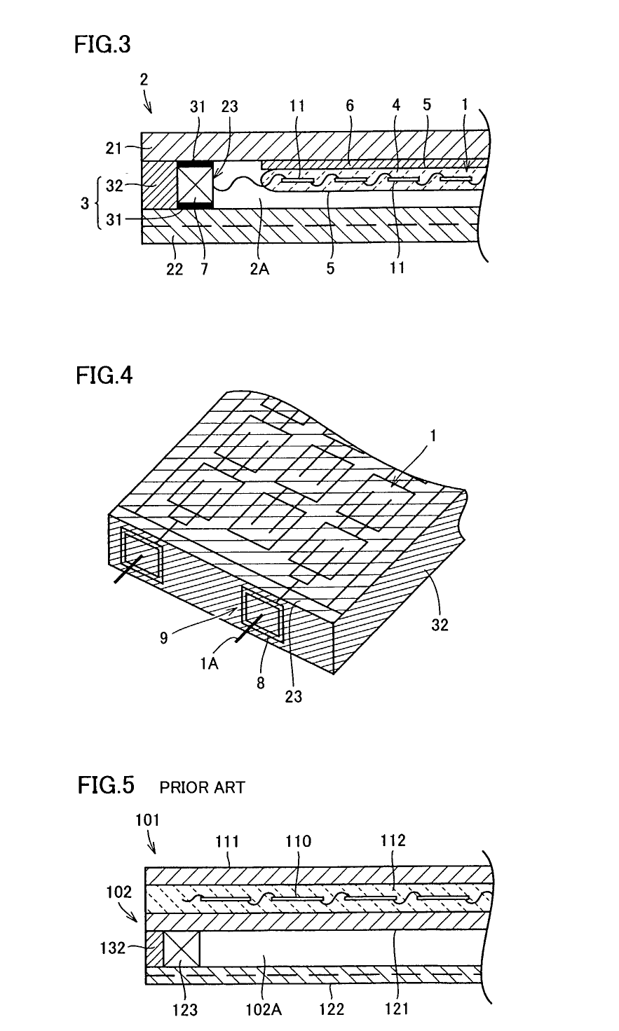

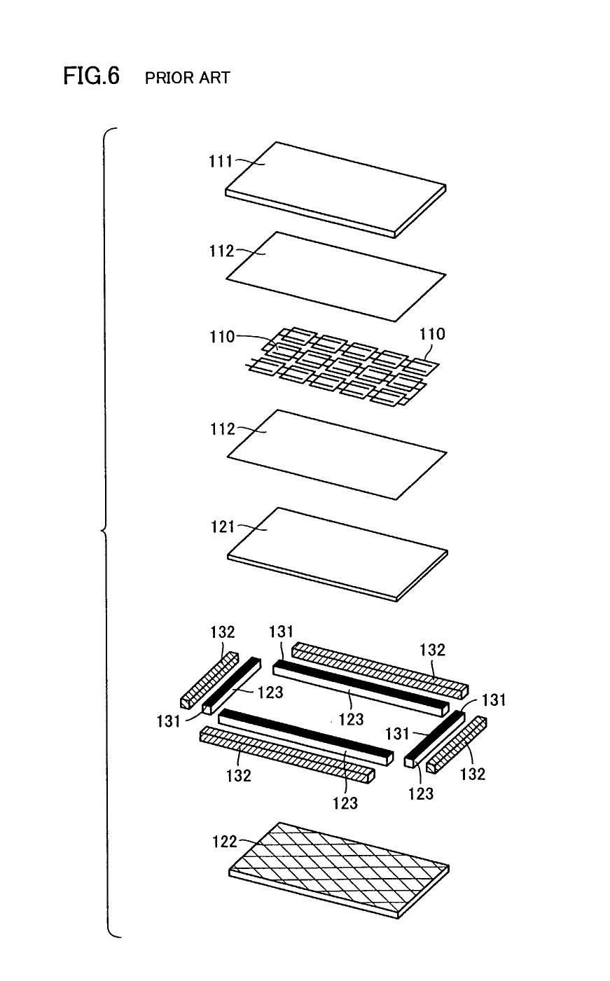

The solar cell module of the present embodiment will be described with reference to FIGS. 3 and 4.

The solar cell module of the present embodiment has almost the same structure as the solar cell module of the first embodiment, except that the solar cell train 1 is adhered to the inner surface (the surface facing inner space 2A) of back cover glass 22 in the solar cell module of the first embodiment, while the solar cell train 1 is adhered on the inner surface (the surface facing inner space 2A) of front cover glass 21 in the solar cell module of the second embodiment. The solar cell train 1 is adhered to the glass by a transparent adhesive tape 6 (or transparent resin) such as ethylene vinyl acetate or polyvinyl butyral.

In this manner, in the solar cell module of the present embodiment, the solar cells 11 are adhered on the side of front cover glass 21. Therefore, in the solar cell module of the present embodiment, because of the relation in the index of refraction of the front cover glass 21 and transparent adhesive tape 6 (or transparent resin), the amount of sunlight (amount of incident sunlight) reaching solar cell 11 is increased as compared with the solar cell module in accordance with the first embodiment shown in FIG. 1. Therefore, by the solar cell module of the present embodiment, the power output from the solar cell train 1 can be increased.

Further, as shown in FIG. 4, a power output portion 9 is provided on a side surface of spacer 23. Further, a hermetic seal 8 is provided around the periphery of power output portion 9. Therefore, air tightness and waterproof of solar cell module can be ensured. The hermetic seal may be provided by an O ring.

As the secondary sealing member for ensuring air tightness and waterproof of the solar cell module, sealing member 32 such as silicone, polysulfide or rubber is used.

In the structure of the solar cell module shown in FIG. 4, a lead 1A is connected to power output portion 9. In place of lead 1A, a terminal may be used.

In the solar cell modules of the first and second embodiments, a plurality of solar cells 11 (or a single solar cell 11) are subjected to weather resistant sealing process using transparent filler 4 and weather resistant and transparent film 5. Therefore, even when moisture enters the inner space 2A as the air-tight and waterproof sealing member 3 deteriorates, reliability over a long period of time generally required of a solar cell module can be maintained.

Further, the solar cell train 1 that has been subjected to weather resistant sealing process is adhered on the inner surface (the surface facing inner space 2A) of front cover glass 21 or on the inner surface (the surface facing inner space 2A) of the net-embedded glass 22. Therefore, the sealing member used for the weather resistant sealing process functions as a buffer that is relatively thick. Accordingly, solar cell 11 is not in direct contact with front cover glass 21 or net-embedded glass 22. As a result, heat transmission between the metal portion of the front or rear surface electrode of solar cell 11 and front cover glass 21 or net-embedded glass 22 becomes less likely. Thus, even when a strong sunlight enters the solar cell module, possibility of heat crack of the glass, or possibility of crack generated in solar cell 11 because of significant difference in coefficient of layer expansion between solar cell 11 and front cover glass 21 or net-embedded glass 22, can be reduced.

The solar cell modules of the first and second embodiments described above can be installed on a building by the construction work similar to that for the conventional double glazing glass. As a result, the present invention significantly contributes to wide spread use of the solar cell module integrated with the construction members.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar cell module, including
a double glazing glass having two sheet glasses superposed at a prescribed distance with a spacer therebetween, said two sheet glasses and said spacer forming an inner space of a sealed state, comprising
a plurality of solar cells that have been subjected to weather resistant sealing process, provided in said inner space.

2. The solar cell module according to claim 1, wherein
in said weather resistant sealing process, said solar cells are sealed individually one by one or by a unit of solar cell group including a plurality of solar cells.

3. The solar cell module according to claim 1, wherein
in said weather resistant sealing process, said plurality of solar cells are all integrally sealed.

4. The solar cell module according to claim 1, wherein
in said resistant sealing process, a transparent filler is used.

5. The solar cell module according to claim 4, wherein
said transparent filler is transparent resin of ethylene vinyl acetate or polyvinyl butyral.

6. The solar cell module according to claim 1, wherein
in said weather resistance sealing process, a weather resistant and transparent film is used.

7. The solar cell module according to claim 6, wherein
said weather resistant and transparent film is polyethylene terephthalate or fluorine based resin film.

8. The solar cell module according to claim 1, wherein
said plurality of solar cells are attached to a surface facing said inner space of said sheet glass on sunlight receiving side, of said double glazing glass.

9. The solar cell module according to claim 1, wherein
said plurality of solar cells are attached to a surface facing said inner space of said sheet glass on a sunlight non-receiving side, of said double glazing glass.

10. The solar cell module according to claim 1, wherein
said plurality of solar cells are attached to one sheet glass of said double glazing glass with a fixing filler interposed.

11. The solar cell module according to claim 10, wherein
said fixing filler is a transparent adhesive tape or a transparent resin including ethylene vinyl acetate or polyvinyl butyral.

12. The solar cell module according to claim 1, wherein
said sheet glass on the sunlight non-receiving side of said double glazing glass is a net-embedded glass.

13. The solar cell module according to claim 1, wherein
said spacer includes a conductive portion to which power output from said plurality of solar cells is supplied, and
a power output portion capable of externally outputting power of said plurality of solar cells is connected to said conductive portion.

14. The solar cell module according to claim 13, wherein
a sealing member is provided between said power output portion and each of said two sheet glasses.

15. The solar cell module according to claim 1, wherein
an air-tight and waterproof seal is provided around a peripheral portion of each of said two sheet glasses, between each of said two sheet glasses and said spacer.
